(19) United States
(12) Patent Application Publication
(10) Pub. No.: US 2002/0001861 A1
(43) Pub. Date: Jan. 3, 2002

(54) Electrostatic protection circuit

(75) Inventor: Masahiko Ohuchi, Tokyo (JP)

Correspondence Address: SUGHRUE, MION, ZINN, MACPEAK & SEAS, 2100 Pennsylvania Avenue, N.W., Washington, DC, 20037, US

(73) Assignee: NEC CORPORATION

(21) Appl. No.: 09/891,350

(22) Filed: Jun. 27, 2001

(30) Foreign Application Priority Data
Jun. 29, 2000 (JP) 195609/2000

(51) Int. Cl. H01L 21/00; C23F 1/00

(52) U.S. Cl. 438/9; 438/7; 156/345; 216/69; 216/67

(57) ABSTRACT

The present invention provides an etching apparatus and a method of preventing electrical damage of the device due to the charge-up and preventing a wiring short due to etching residues when forming wiring on the device formed in a semiconductor substrate. In a wiring etching method in a semiconductor substrate, including a step of a conductor in a semiconductor device by plasma etching, the etching of the above conductor under a Continuous Wave condition (a condition where a plasma discharge occurs continuously) is performed to a predetermined film thickness before the entire conductor is etched, and after that the etching is performed under a Time Modulation condition (a condition where a plasma discharge occurs intermittently) thereafter.

### BACKGROUND OF THE INVENTION

1. Field of the Invention

The present invention relates to a device and manufacturing method of a semiconductor device to form wiring on the device composed of semiconductor elements or the like which are electrically connected to the device, and particularly but not limited, to a plasma etching technique of a metal wiring. The present application is based on Japanese Patent Application No. 195609/2000, which is incorporated herein by reference.

2. Background

In manufacturing a semiconductor device, a device such as a transistor on a semiconductor substrate is formed by placing wiring such as metal and polysilicon wiring on a top layer of the device, and then electrically connecting the devices alternately using the wiring. FIG. 1A is a simplified cross-sectional view to describe this type of wiring. As shown in FIG. 1A, after an element forming region is defined by forming a separation insulating film 102 on a semiconductor substrate 101, a MOS transistor composed of a gate insulating film 103, a gate electrode 104, and an impurity diffusion layer 105 is formed as a device in the element forming region. Moreover, an inter-layer insulating film 106 is formed on the entire surface and a contact hole 107 is formed for an electric connection of wiring to the device. Here, the contact hole 107 is formed for an electric connection of wiring to the gate electrode 104. Then, a metal film 108 as a wiring material is formed on the entire surface of the inter-layer insulator 106 including contact hole 107, making it possible to form a wiring 108′ which is electrically connected to gate electrode 104 by etching selectively metal film 108 to a certain pattern using a photolithography technique.

In such a manufacturing method, an etching technique using a plasma such as reactive ion etching is used as a technique to etch selectively a metal film 108. Therefore, due to the plasma generated for etching, electric charges accumulate on the metal film 108, which is the etched member, namely a charge-up occurs. This electric charge is transmitted to the gate electrode 104 in the device through the contact hole 107 and causes electric damage to the device. Especially, in recent semiconductor devices with decreased feature size of the devices, the ratio between the wiring 108′ side area and the gate area, namely the antenna ratio, becomes extremely large. In an example of a pattern shape of the wiring 108 shown in FIG. 1B, the ratio of the wiring side area (a thickness of the metal film a peripheral length of the wiring) to the gate area can be equal to or more than 5000:1. On the other hand, the minimum distance d between two micro-wirings is about equal to or less than about 0.30 μm. Therefore, in the above etching step, when the metal film 108 is etched over the entire thickness, and when the metal film 108 is etched and separated into each pattern, electrical damage of the device is significantly generated by the charge-up due to the increased antenna ratio.

In order to prevent such damage of the device by the charge-up, as disclosed in Japanese Patent Application Laid-Open No. Hei 11-219938, it is considered effective if a part of the etching step under the CW condition (Continuous Wave condition) shall be substituted by a condition controlling a pulse time, that is the TM condition (Time Modulation condition). Namely, by using the TM condition, the charges on the wiring decrease and it is possible to control the charge-up. The main objective of this patent is to prevent an abnormality of the etching profile due to the charge-up by substituting the CW condition with the TM condition in the etching technique of the wiring film.

This publication also discloses that by substituting the CW condition with the TM condition after the surface of the under-layer of the wiring film is exposed, generation of a local imbalance of ion charges is suppressed, and it is possible to etch the wiring without generation of an abnormality of the etching profile.

However, by examination of the present inventors regarding the published technique, especially in the etching under the TM condition, etching residues are frequently produced and often cause an electric short on the wiring. In a case of forming metal wiring, the surface of the metal film is often not clean because it is oxidized or contaminated by organic substances or the like. Especially, as shown in FIG. 2, when the patterning of a photo resist (PR) 109, which will be used as a mask when the metal film 108 is etched, is conducted again, residues from the photo resist or a stripping solution can be left. Or, chemical changes or deformation on the surface of or inside the metal film can occur (for example, when the photo-resist is stripped at high temperature, Cu in an Al-Cu alloy as the metal film may gather and precipitate). If the metal film is a layered film, an alloy layer which is difficult to etch can be easily formed at the interface. In general, the laminated structure is made by forming a film such as TiN on top of aluminum as the metal film, and in this case an Al-Ti alloy will form at the interface. This structure makes it very difficult to be etched. As a result, after the etching step is completed, the Al-Ti alloy remains as the etching residue 110 shown in FIG. 2. This residue between the wiring 108′ will cause a wiring short and lead to the failure of the device. As described above, recently because of the need to form a wiring which has a micro distance to each other, this type of etching residue 110 causes a wiring short and a possibility of device failure becomes extremely high.

Moreover, in the technique described in the above publication, a technique of switching into a TM condition after the under-layer of the wiring film is exposed, because the etching is performed under a CW condition at the most important moment, just before the wiring film is separated by etching, the charge-up becomes significant and it is difficult to prevent electrical damage to the device.

One object of the present invention is to provide a wiring etching method which prevents electrical damage to the device due to the charge-up when forming wiring, and which prevents generation of wiring shorts due to the etching residue.

### SUMMARY OF THE INVENTION

As the first aspect of the present invention, an etching method of wiring in a semiconductor device, including a step of etching a wiring film formed on a semiconductor substrate by plasma etching, the method being characterized by the steps of: etching the wiring film under a CW condition (a condition where the plasma discharge occurs continuously) to a predetermined film thickness, stopping before the entire wiring film is etched, and etching the wiring film under a TM condition (a condition where the plasma discharge occurs intermittently) thereafter.

As a second aspect of the present invention, the present invention provides an etching method of forming wiring in a semiconductor device, including a step of etching a wiring film formed on a semiconductor substrate by plasma etching, the method being characterized by the steps of: etching the wiring film under a CW condition to a predetermined film thickness, stopping before the entire wiring film is etched, etching the wiring film under a TM condition, and after the entire wiring metal is etched, etching under a CW condition. In this case, it is preferable to switch from the CW condition to the TM condition when the film thickness of the wiring film is measured to have reached a predetermined thickness of the wiring film. It is preferable to use the IEP (Interferometric End Point) technique to measure the thickness of the wiring film.

According to the present invention, by performing etching under a CW condition until the wiring film is etched entirely, the primary factor of causing etching residue after etching is eliminated. Then, performing etching under a TM condition at the moment when wiring film etches through and thereafter prevents electric damage to the device due to the charge-up on the wiring film.

### BRIEF DESCRIPTION OF THE DRAWINGS

The above and other objects, advantages and features of the present invention will be more apparent from the following description taken in conjunction with the accompanying drawings, in which:

FIG. 1A illustrates a cross-sectional view of a semiconductor device that is to be manufactured in the conventional manufacturing method.

FIG. 1B illustrates a wiring pattern view of a semiconductor device that is to be manufactured in the conventional manufacturing method.

FIG. 2 illustrates a cross-sectional view of a apparatus to explain problems in the conventional manufacturing method.

FIG. 3A illustrates a cross-sectional view to explain the manufacturing steps of an embodiment in present invention.

FIG. 3B illustrates a cross-sectional view to explain the manufacturing steps of an embodiment in present invention.

FIG. 3C illustrates a cross-sectional view to explain the manufacturing steps of an embodiment in present invention.

FIG. 4 illustrate a schematic structural view of the etching device.

FIG. 5A illustrates a timing diagram to explain the application of the high-frequency wave in the CW condition.

FIG. 5B illustrates a timing diagram to explain the application of the high-frequency wave in the TM condition.

FIG. 6 shows a view comparing respective steps of the manufacturing method in the present invention and of the conventional manufacturing methods.

FIG. 7 illustrates a schematic structural view of the etching apparatus with an IEP apparatus.

FIG. 8 illustrates a schematic structural figure to indicate another example of the etching apparatus in the present invention.

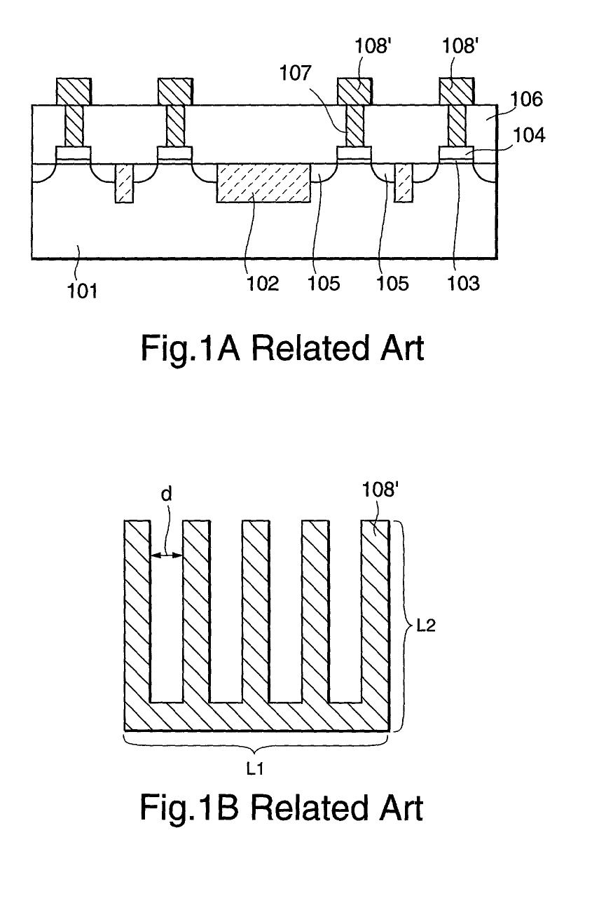

### BRIEF DESCRIPTION OF THE PREFERRED EMBODIMENTS

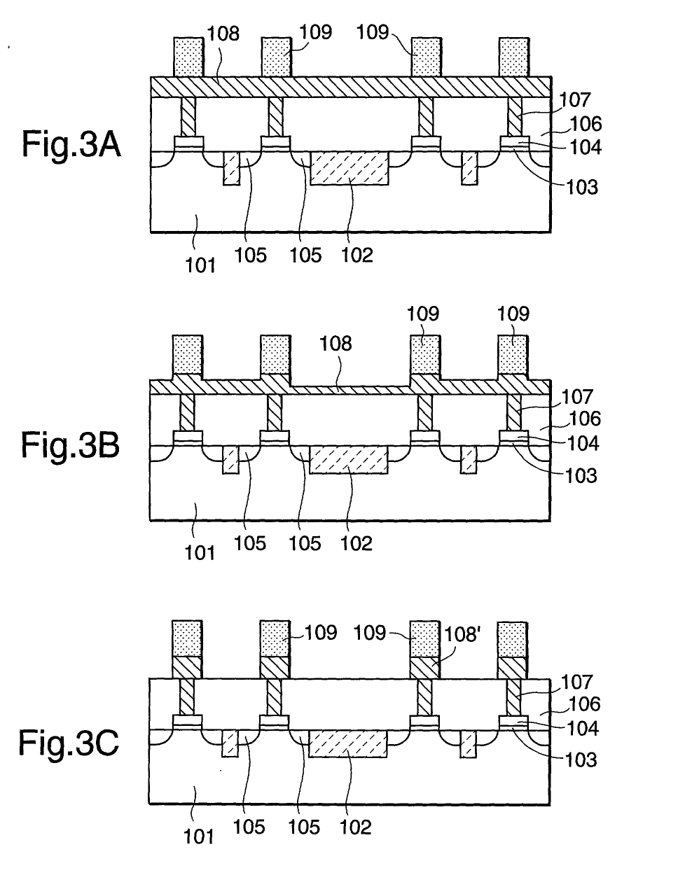

The embodiment mode of the present invention is explained by referring to the figures. FIGS. 3A to 3C are cross-sectional views of the apparatus to explain the etching method in the present invention. First, in FIG. 3A, after a groove for isolation of elements is formed by etching selectively the surface of a silicon substrate 101, an element-forming region is defined and formed together with a separation insulating film 102 formed by filling an insulating film such as a silicon oxide film into the groove. Next, a gate insulating film 103 and a gate electrode 104 are formed by depositing a silicon oxide film and a polysilicon film successively on the surface of the silicon substrate 101 of the element-forming region and etching the layer to a certain pattern. Moreover, an impurity layer (SD) 105 as source and drain regions is formed by implanting an impurity into the silicon substrate 101 which is self aligned toward the gate electrode 104. With this, a MOS transistor is formed. Next, an inter-layer insulating film 106 such as PBSG and BSG is formed on the front surface and a contact hole 107, where the gate electrode 104 is exposed, is formed in the inter-layer insulating film 106 for an electric connection of wiring to the MOS transistor. Then, a metal film 108 is formed on the entire surface as a wiring material for an electric connection of wiring to the gate electrode 104 through the contact hole 107. A photo resist 109 is applied on the metal film 108, and the pattern of the photo resist 109 is formed as the resulting wiring pattern.

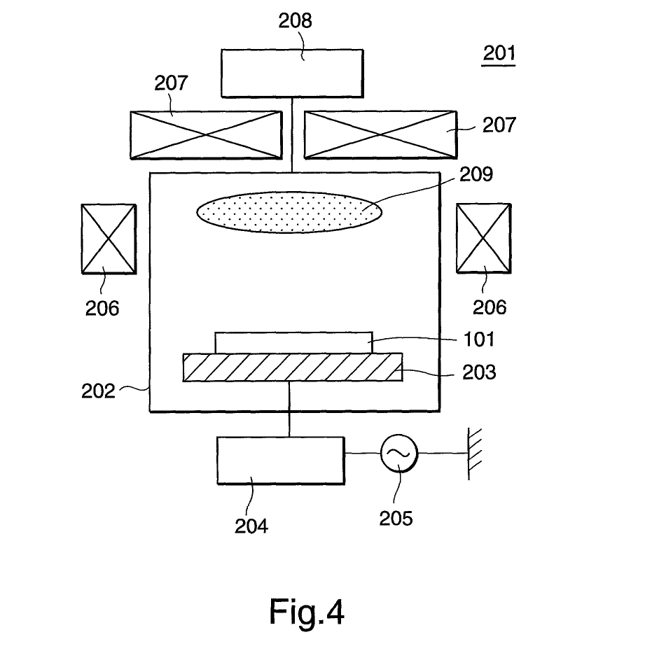

In the plasma etching apparatus 201 shown in FIG. 4, metal film 108 is etched using photo resist 109 as a mask. The plasma etching apparatus 201 in the present invention is an example of an ECR etching device. A lower electrode 203 is arranged inside a chamber 202 where the etching gas (not shown in the figure) is introduced, and high-frequency power (RF) is applied from a high-frequency power source 205 through a signal circuit 204 which is located outside the chamber 202. Magnetic coils 206 and 207 for generating plasma 209 are arranged outside the chamber 202. Further, a microwave circuit 208 for supplying microwaves within the chamber 202 is connected with the chamber 202. The silicon substrate 101 is placed on the lower electrode 203, the high-frequency power is applied to the lower electrode 203 from the high-frequency power source 205, and the etching gas is introduced from a source of the etching gas (not shown in the FIG. 4) inside the chamber 202. Further, by supplying microwaves from the microwave circuit 208, plasma 209 is generated in the chamber 202 and the metal film 108 on the surface of the silicon substrate 101 is etched.

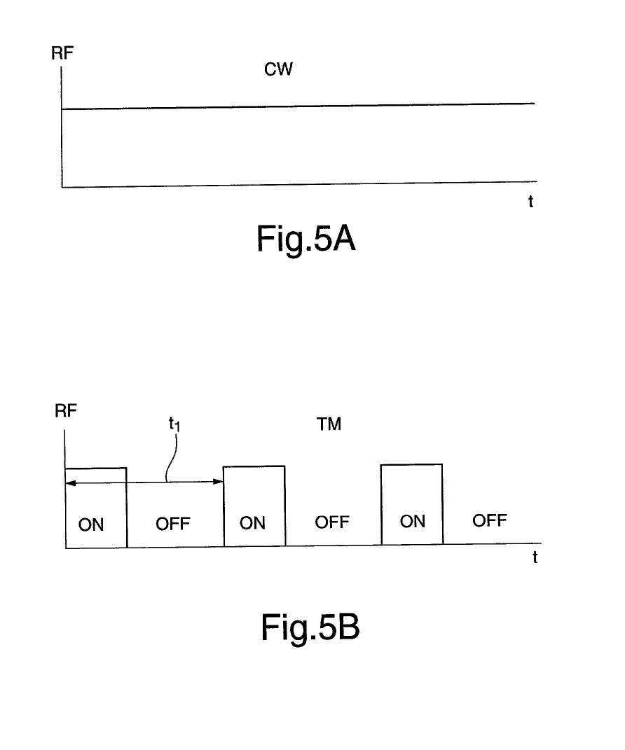

In the beginning of etching the metal film 108 shown in FIG. 3A, the etching is performed under a CW condition by the signal circuit 204 continuously supplying high-frequency power from the high-frequency power supply 205 to the lower electrode 203, as shown in the timing diagram in FIG. 5A. Then, as shown in FIG. 3B, when the metal film 108 is etched to a predetermined thickness, that is when the metal film 108 is not etched entirely and when the inter-layer insulator 106, an under-layer, is not exposed, the etching condition is switched to a TM condition by the signal circuit 204 intermittently supplying high-frequency power on the time axis in FIG. 5B. In this embodiment, as shown in FIG. 3C, the etching under a TM condition is continued until the metal film is etched entirely and the etching is completed. In FIG. 5B, t₁ indicates a cycle of the high-frequency wave power. In addition, although the silicon substrate 101 is processed in the same chamber 202 without being exposed to air at all, plasma discharge may be stopped once or not stopped when the CW condition is switched to the TM condition.

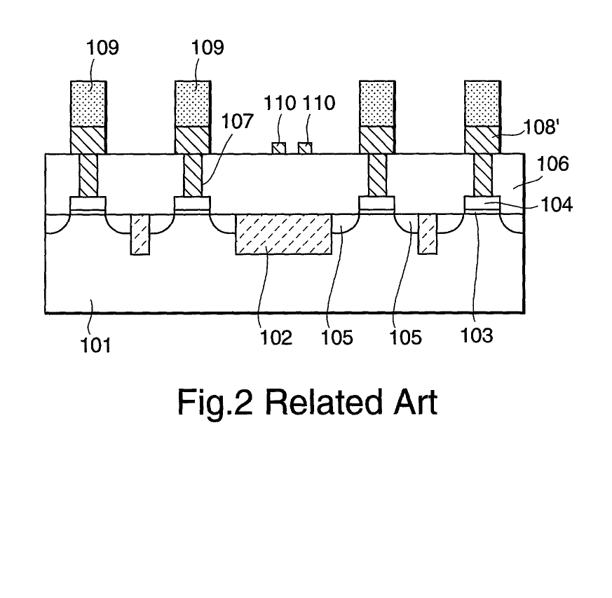

In this embodiment, when metal film 108 is etched to a predetermined thickness before the film is etched entirely, a CW condition is used, and then the etching under a TM condition is performed. As described above, etching under a TM condition as compared to the CW condition causes a problem of generating the etching residue. The mechanism of producing etching residues is due to a lack of bias power. That is, in order to etch the metal film 108 without excessively etching the photo resist 109 on the metal film 108 (high selectivity ratio of the metal film to the photo resist film), it is necessary to control ion energy to draw plasma gas onto the surface of the silicon substrate 101. Under a TM condition, when the photo resist 109 is to be preserved, the ion energy under the TM condition ranges from 1/10 times to 1/2 times that of the CW condition. In this case, materials having a strong bonding energy such as etching residues and oxides will be difficult to etch. Therefore, the surface of the metal film 108, where these materials that are difficult to etch accumulate should be etched under a CW condition. On the other hand, in order not to have the charge-up, before the metal is separated see FIG. 3B, the etching condition should be switched to a TM condition. Because of the above, the production of the etching residue 110 as shown in FIG. 2 is prevented, and the electric damage of the device due to the charge-up is prevented.

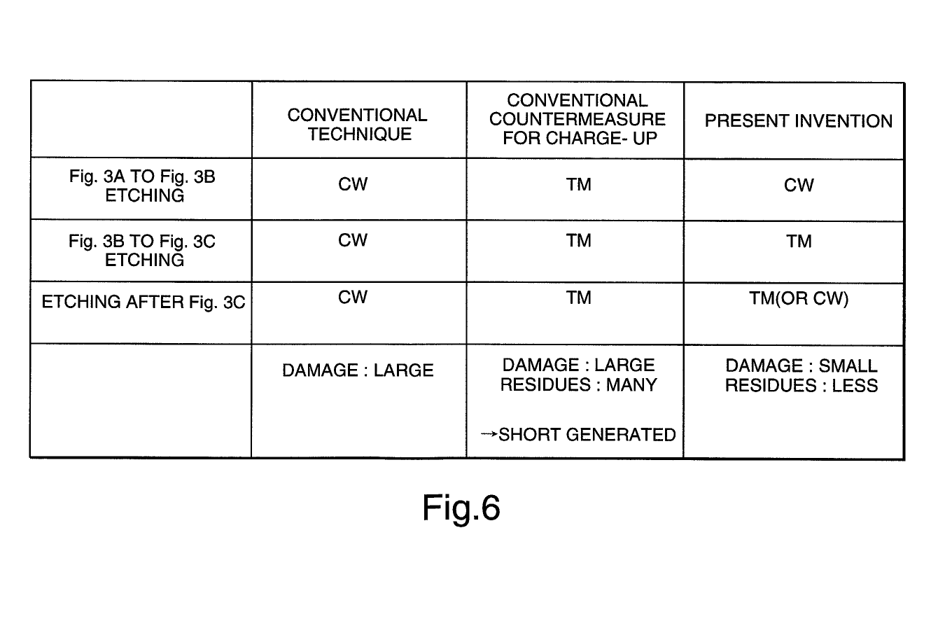

Further, the characteristics (merit) of the etching condition in this embodiment, the conventional technique etching only under a CW condition, and the conventional technique etching only under a TM condition to prevent the charge-up described in the above publication are shown in FIG. 6. It is obvious from FIG. 6 that the damage of the device is large due to the charge-up when the etching is performed only under a CW condition, and that wiring shorts occur due to etching residue when the etching is performed only under a TM condition. On the other hand, in this embodiment, it is possible to decrease the damage to the device and also to decrease the etching residue.

In the above embodiment mode, etching under a TM condition is performed after the metal film 108 is separated completely. As shown in the parentheses in FIG. 6, the etching can be returned to a CW condition after the metal film 108 is separated completely. This is because the damage to the device by the charge-up can easily occur at the moment when the metal film 108 is separated, and not after the metal film 108 is completely separated. Therefore, after the metal film is separated, by performing etching under a CW condition as a step to remove the etching residue, it is possible to remove the etching residue more effectively, to prevent wiring shorts, and to improve the yield.

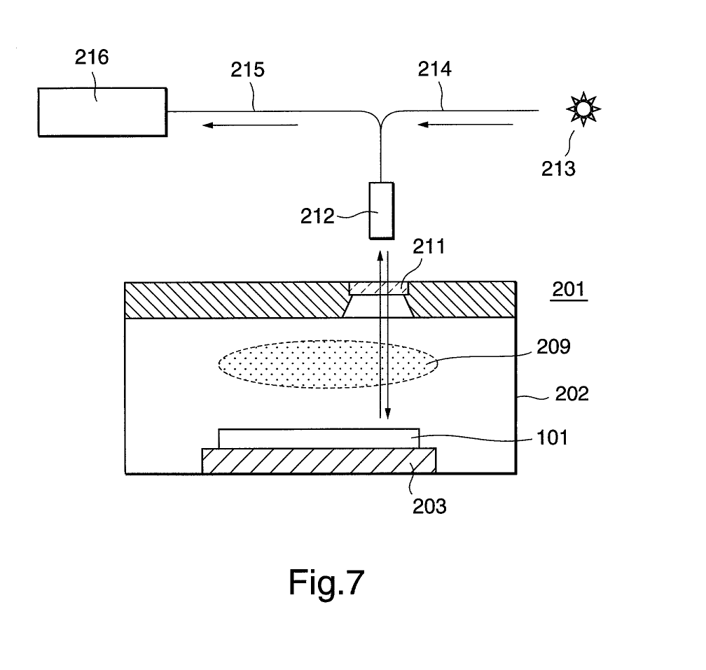

As a technique to detect the timing of switching a CW condition to a TM condition, IEP (Interferometric End Point) may be used. By using this technique and etching under a CW condition as long as possible, it is possible to prevent etching residue. IEP, is a technique as an interferometric film thickness measurement technique, conventionally used to prevent over etching. A schematic structure of the apparatus is shown in FIG. 7. A light permeable window 211 is formed on the upper surface of the chamber 202 of the etching apparatus 201, a collimator 212 is provided in a position facing the window 211 to project the light reflected from the light source 213 through the optical fiber 214 by the collimator 212 to the surface of the silicon substrate 101. The light reflected on the surface of the silicon substrate 101 is received by the collimator 212, travels through an optical fiber 215, and is analyzed by a photometric analyzer 216. Using this apparatus, from the light interference state of the metal film 108 on the surface of the silicon substrate 101, an optical path difference between the surface of the metal film 108 under the mask (photo resist) 109 and the etched surface of the metal film 108 is detected, and from the optical path difference, it is possible to measure the film thickness of the remaining metal film 108. Therefore, by etching under a CW condition using IEP and by switching a CW condition to a TM condition when the film thickness of the remaining metal film 108 reaches a predetermined film thickness, it is possible to switch a CW condition to a TM condition before the metal film 108 is separated completely. Using IEP, it is possible to etch a metal film with various film thicknesses and various etching rates. In any case, using IEP promotes the effects described above.

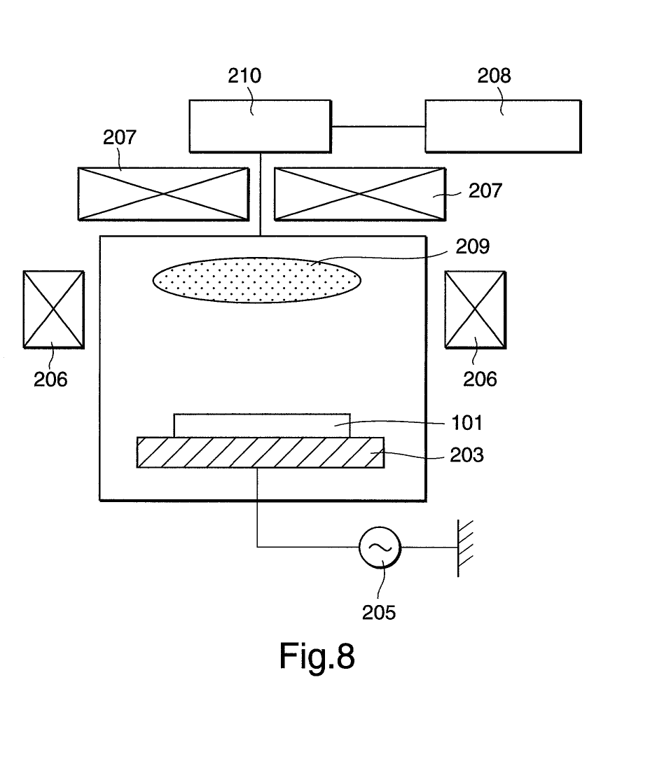

In the above embodiment, etching under a TM condition is performed by pulsing the bias power (called bias TM), that is high-frequency power applied to lower electrode 203 of the etching apparatus 201 continuously or intermittently in a signal circuit 210. As shown in FIG. 8, it is also possible to perform etching under a TM condition by generating a pulse of a plasma discharge (called source TM) by supplying microwaves continuously or intermittently, by the microwave circuit 208 in the chamber 202 by using the signal circuit 204.

As described above, this invention enables the manufacture of a highly reliable semiconductor device which has no electric damage and no wiring shorts by eliminating a cause of etching residue by performing etching under a CW condition until the wiring film is etched to the entire thickness and separated, and by preventing electric damage to the device due to the charge-up on the wiring film by performing the etching under a TM condition at the moment the wiring film is separated and after. In this case, after the wiring film is etched to the entire thickness under a TM condition, it is possible to prevent the etching residue more preferably by etching again under a CW condition.

The present invention is not limited to the above embodiments, and it is contemplated that numerous modifications may be made without departing from the spirit and scope of the invention. The ECR etching apparatus described above with reference to the figures as an example of the etching device, is merely an exemplary embodiment of the invention, and the scope of the invention is not limited to these particular embodiments. It is possible to apply this invention to other etching devices such as an SWP method, an inductive coupling plasma method, and helicon source plasma etching devices. Accordingly, other structural configurations may be used, without departing from the spirit and scope of the invention as defined in the following claims.

What is claimed is:

1. A method of etching a wiring film of a semiconductor device in an etching apparatus, comprising the steps of:
etching said wiring film under a Continuous Wave condition where a plasma discharge occurs continuously to a predetermined thickness, the predetermined thickness being defined to be less than a thickness of said wiring film; and
etching said wiring film under a Time Modulation condition where a plasma discharge occurs intermittently.

2. The method of etching a wiring film as claimed in claim 1, further comprising the steps of:
detecting a film thickness of said wiring film; and
changing said Continuous Wave condition to said Time Modulation condition when said film thickness is substantially equal to said predetermined thickness.

3. The method of etching a wiring film as claimed in claim 2, wherein said film thickness of said wiring film is detected by an Interferometric End Point technique.

4. The method of etching a wiring film as claimed in claim 1, further comprising the step of:
stopping said plasma discharge before said step of changing said Continuous Wave condition to said Time Modulation condition.

5. The method of etching a wiring film as claimed in claim 2, further comprising the step of:
stopping said plasma discharge before said step of changing said Continuous Wave condition to said Time Modulation condition.

6. The method of etching a wiring film as claimed in claim 1, further comprising the step of:
supplying a high-frequency power to said etching apparatus intermittently under said Time Modulation condition.

7. The method of etching a wiring film as claimed in claim 1, further comprising the step of:
supplying microwaves to said etching apparatus intermittently under said Time Modulation condition.

8. A method of etching a wiring film in a semiconductor device in an etching apparatus, comprising the steps of:
etching said wiring film under a first Continuous Wave condition where a plasma discharge occurs continuously to a predetermined thickness, the predetermined thickness being defined to be less than a thickness of said wiring film;
etching said wiring film under a Time Modulation condition where a plasma discharge occurs intermittently until said wiring film is entirely etched in the thickness direction; and
changing said Time Modulation condition into a second Continuous Wave condition.

9. The method of etching a wiring film as claimed in claim 8, further comprising the steps of:
detecting a film thickness of said wiring film; and
changing said first Continuous Wave condition to said Time Modulation condition when said film thickness is substantially equal to said predetermined thickness.

10. The method of etching a wiring film as claimed in claim 9, wherein said film thickness of said wiring film is detected by an Interferometric End Point technique.

11. The method of etching a wiring film as claimed in claim 8, further comprising the step of:
stopping said plasma discharge before said step of changing said first Continuous Wave condition of said Time Modulation condition.

12. The method of etching a wiring film as claimed in claim 9, further comprising the step of:
stopping said plasma discharge before said step of changing said first Continuous Wave condition of said Time Modulation condition.

13. The method of etching a wiring film as claimed in claim 8, further comprising:
supplying a high-frequency power to said etching apparatus intermittently under said Time Modulation condition.

14. The method of etching a wiring film as claimed in claim 8, further comprising:
supplying microwaves to said etching apparatus intermittently under said Time Modulation condition.

15. An etching apparatus for etching a wiring film of a semiconductor device, comprising:
continuous wave etching means for continuously etching said wiring film to a predetermined thickness, the predetermined thickness being defined to be less than a thickness of said wiring film; and
time modulation etching means for intermittently etching said wiring film.

16. The etching apparatus according to claim 15, further comprising film thickness detecting means for measuring the film thickness of said wiring film.

17. The etching apparatus according to claim 15, wherein said continuous wave etching means receives a signal from a high-frequency power source.

18. The etching apparatus according to claim 15, wherein said time modulation etching means receives a signal from a microwave source.
